(19) United States
(12) Patent Application Publication
(10) Pub. No.: US 2006/0140320 A1
(43) Pub. Date: Jun. 29, 2006

(54) Mechanism to adjust a clock signal based on embedded clock information

(76) Inventors: Richard S. Jensen, Gilbert, AZ (US); Dave Dunning, Portland, OR (US); Sanjay Dabral, Palo Alto, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/021,953

(22) Filed: Dec. 23, 2004

(51) Int. Cl. H03D 3/24

(52) U.S. Cl. 375/376

(57) ABSTRACT

An apparatus and method to improve bandwidth and reduce phase error in a tracking receiver is presented. According to one embodiment, an apparatus is presented comprising a phase comparator to generate indications based on a phase of a local clock signal and transitions in a stream of received data, an electoral loop filter to generate a phase shift signal based on the indications received from the phase comparator in a time interval, and a local clock controller to adjust the local clock signal based on the signal asserted from the electoral loop filter. The phase shift signal is either a phase increment signal or a phase decrement signal that is issued according to the majority of either increment indications or decrement indications received during the time interval.

### FIELD OF THE INVENTION

The present embodiments of the invention relate generally to high speed input/output circuits and, more specifically, relate to tracking receiver circuits used to detect clock phase information embedded in data streams.

### BACKGROUND

Many digital electronic systems, including computer systems, include more than a single device. The multiple devices within a system may be coupled to each other by way of interconnects. One type of interconnect may stream serial data across its medium from a transmitting device to a receiving device. For reliable reconstruction of data received at the receiving device, the timing reference (e.g., clock edge positions) used by the receiving device should. resemble the timing reference used at the transmitting device.

In many data communication arrangements, separate clock signals are not transmitted with the data. This requires recovering the clock from the data at the receiving end in order to then recover the data itself. When transmitting the clocked data across a transmission medium, noise in the data signal, such as jitter and phase skew reduces the sampling window for the data. High data rates mean the receiving device needs to operate within shrinking timing windows. Furthermore, with increased data rates, the transmission medium becomes more lossy, thereby shrinking the margins in the voltage axis and making it more difficult to recover the data. Therefore, accurate phase tracking is becoming increasingly important.

For clock recovery that reduces the phase error to a minimum between the transmitter clock and the receiver clock, sufficient transition density needs to be inserted into the data stream. When a received information stream does not contain a sufficient number of transitions (e.g., a data stream of “000000” is received), the receiver may be unable to adjust the local receiver clock signal to track the transmitter clock signal observed at the receiver.

Conventionally, 8b10b encoding schemes are used to provide transition density. The overhead associated with 8b10b encoding may be unacceptable in a latency-strapped system and cause reduced efficiency of the system, because ten bits must be transmitted to send eight bits of information. If non-8b10b encoded links are employed in a data communication arrangement, the transition density guarantee is substantially lower than with 8b10b encoded links. In such an environment, clock recovery can be severely hampered as the receiver cannot track a substantial portion of the transmitter drifts.

Previous architectures of clock and data recovery schemes used a voting-based scheme for tracking the phase of the embedded clock data. The votes were derived from the transitions in the data received from the data channel. The previous architecture determined whether a local receiver clock's edge or phase position should be adjusted to accommodate the jitter from the transmit clock and local receive clock. A signal was then asserted to “vote” appropriately to increment or decrement the phase. This signal went into a proportional loop filter. A proportional loop filter is a particular design of a loop filter that accumulates votes. The filter typically slowed down the response. The filter used a threshold vote level, and when the votes accumulated to that threshold vote level, a signal was generated to increment or decrement the phase.

In previous architectures it had to be ensured that the tracking unit received the necessary minimum number of votes. On the other hand, if the number of votes was too numerous because of latency of the loop, the tracking scheme caused the sampling clock phases to move in the wrong direction for certain frequencies of phase variation. Furthermore, since no phase adjustment could be made until the threshold vote level was met, a lack of tracking occurred.

### BRIEF DESCRIPTION OF THE DRAWINGS

The present invention will be understood more fully from the detailed description given below and from the accompanying drawings of various embodiments of the invention. The drawings, however, should not be taken to limit the invention to the specific embodiments, but are for explanation and understanding only.

FIG. 1 illustrates a block diagram of a communication system;

FIG. 2 illustrates a block diagram of one embodiment of a receiver circuit;

FIG. 3 illustrates a block diagram of one embodiment of a receiver tracking unit;

FIG. 4 illustrates a graphical representation of one embodiment of an electoral loop filter's signal-generation procedure;

FIG. 5 illustrates a circuit diagram of one embodiment of a receiver tracking unit;

FIG. 6 depicts a graphical representation of bandwidths of embodiments of the present invention;

FIG. 7 illustrates a local receiver clock signal error as a function of transition density;

FIG. 8 illustrates a flow diagram depicting one embodiment of using a receiver tracking unit to adjust a local receiver clock; and

FIG. 9 illustrates a flow diagram depicting one embodiment of using an electoral loop filter to determine phase adjustments of a local receiver clock.

### DETAILED DESCRIPTION

A method and apparatus to adjust a clock signal based on embedded clock information. Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

In the following description, numerous details are set forth. It will be apparent, however, to one skilled in the art, that the embodiments of the invention may be practiced without these specific details. In other instances, well-known structures and devices are shown in block diagram form, rather than in detail, in order to avoid obscuring the present invention.

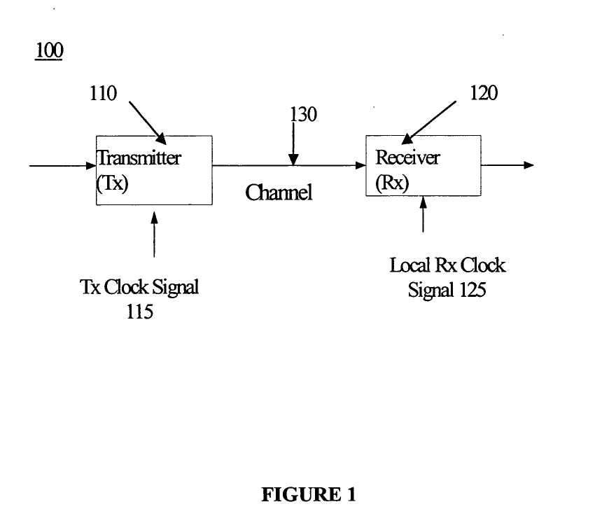

FIG. 1 is a block diagram of one embodiment of a communication system 100 that may be used to improve bandwidth and reduce phase error in a tracking receiver. The system 100 includes a transmitter (Tx) 110, a data signal channel 130, and a receiver (Rx) 120.

Transmitter 102 transmits a data signal over channel 130 to receiver 120. The original signal may be generated by the transmitter 110 in accordance with a Tx clock signal 115. After the information travels through the channel 130, the receiver may then re-create the original signal in accordance with the received signal and a local Rx clock signal 125.

To accurately re-create the original signal, the phases of the local Rx clock signal 125 and the Tx clock signal 115 as seen at the receiver 120 should be aligned as closely as possible. This is typically done by using the received information stream to “recover” information about the Tx clock signal 115. That is, “transitions” in the received information stream (i.e., from 0 to 1 or from 1 to 0) will reflect transitions in the Tx clock signal 115. By adjusting the local Rx clock signal 125 in accordance with these transitions, the phase error between the local Rx clock signal 125 and the Tx clock signal 115 may be reduced.

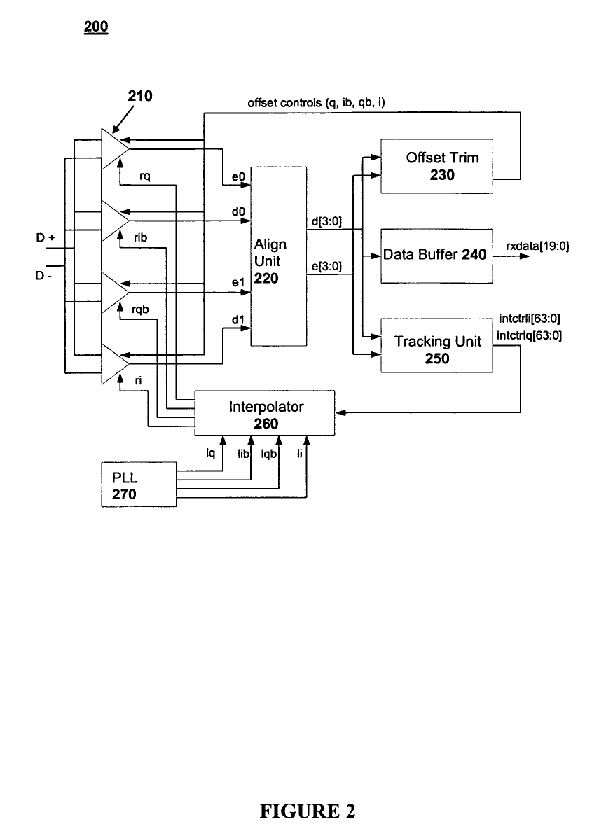

FIG. 2 is a block diagram illustrating one embodiment of a receiver circuit 200. In one embodiment, receiver circuit 200 may be implemented in receiver 120 of FIG. 1. Receiver circuit 200 includes a plurality of circuit elements, such as front amplifiers 210, an align unit 220, an offset trim unit 230, a data buffer 240, a tracking unit 250, an interpolator 260, and a phase locked loop 270. Front amplifiers 210 are arranged to receive and amplify data from an I/O link, such as from channel 130 in FIG. 1. Align unit 220 is arranged to align and synchronize data and edge samples to a single recovered clock edge. Offset trim unit 230 provides a mechanism to automatically trim the inherent voltage offset of phase comparators in the tracking unit 250. The data buffer 240 performs character alignment and, in some embodiments 4 bit to 20 bit conversion. The tracking unit 250 dynamically adjusts the phase of a local clock, i.e., PLL 270, so that it tracks the clock that is embedded in the transmitted data. Interpolator 260 derives a clock with variable phase based on signals received from the tracking unit 250, using several phases of the fixed local clock produced by PLL 270.

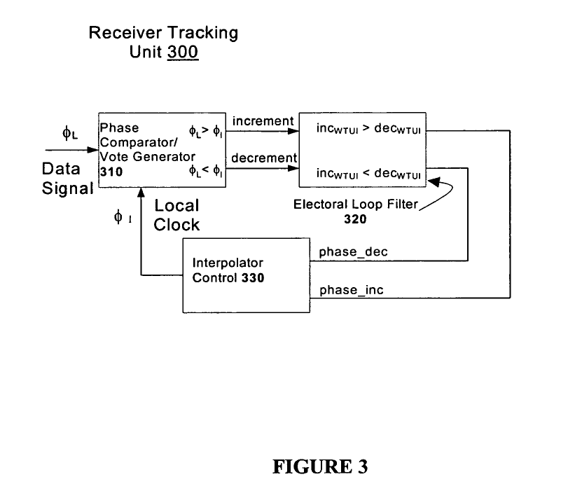

FIG. 3 illustrates a block diagram of one embodiment of a receiver tracking unit 300. In one embodiment, tracking unit 300 may be tracking unit 250 of FIG. 2. Receiver tracking unit 300 includes a phase comparator/vote generator unit 310, an electoral loop filter unit 320, and an interpolator control unit 330. In a serial data delivery approach, where the clock is recovered from the data stream, the tracking portion of the receiver is important to reduce the phase error associated between the transmit clock and the local receive clock. The jitter associated with PLL clocks can introduce a variety of amplitude and frequencies of jitter. Some of this jitter is tracked and compensated for using the receiver tracking circuitry.

The phase comparator/vote generator unit 310 receives a data signal that includes embedded clock information from the transmitter. It then compares the data transition phase in the data with a local clock phase to determine if the local clock is either leading or lagging with respect to the embedded clock. Trends in the embedded transmitter clock can be tracked assuming that the data transition times are correlated to the embedded clock by observing it over a long period of time.

The phase comparator/vote generator unit 310 then sends a signal correlating to whether the local clock was leading or lagging. The signal from the phase comparator/vote generator unit 310 is identified by various terminologies; in some embodiments it may be known as a “vote”, and in yet other embodiments it may be known as an “indication”. Generally, this signal identifies the position of the phase of the local receiver clock as compared to the phase of the embedded clock data of the received data.

In one embodiment, an increment vote is sent if the local clock phase is lagging, and a decrement vote is sent if the local clock is leading. An increment vote is a vote to adjust the local receiver clock's phase or edge position to the right. A decrement vote is a vote to adjust the local receiver clock's phase or edge position to the left.

The electoral loop filter unit 320 receives the increment or decrement vote from the phase comparator/vote generator unit 310. The electoral loop filter unit 320 tracks the number of increment and decrement votes accumulated during a window time unit interval (WTUI). At the end of the window time unit interval, the majority of increment votes versus decrement votes received during the interval causes the electoral loop filter to assert a phase increment signal or phase decrement signal to the interpolator control unit 330.

More specifically, if the number of increment votes asserted in the window time unit interval were greater than the number of decrement votes asserted in the same interval, then a phase increment signal is be sent to the interpolator/interpolator control unit 330. If the number of decrement votes asserted in the window time interval is greater than the number of increment votes asserted in the same interval, then a phase decrement signal is sent to the interpolator/interpolator control unit 330.

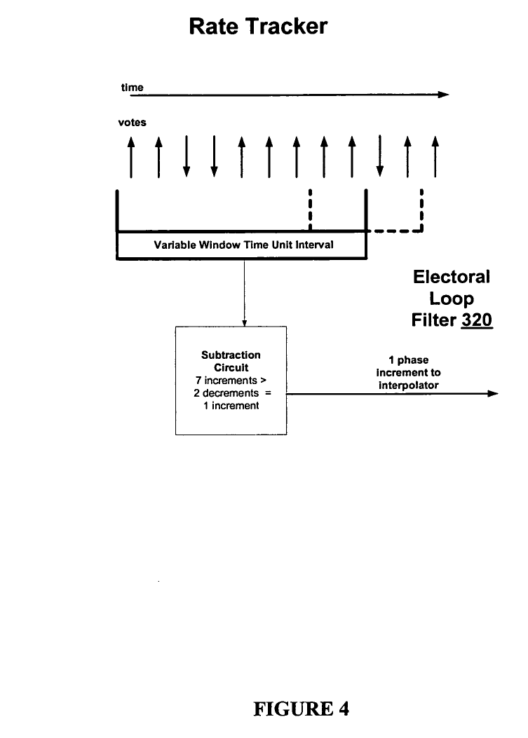

FIG. 4 is a graphical illustration of one embodiment of the electoral loop filter's 320 signal generation procedure. In one embodiment, various increment and decrement votes are tracked in the electoral loop filter during a variable window time unit interval. Once this window time unit interval has ended, subtraction circuitry within the electoral loop filter determines the greater of the increment and decrement votes asserted during the interval. A phase increment or phase decrement signal is then asserted depending on which type of vote is in the majority.

The window time unit interval in the electoral loop filter 330 depends on particular product specifications and tracking loop latency. Once a window time unit interval is established in a tracking receiver, it will remain uniform throughout the clock recovery process. At initial set up, the window time unit interval may be set to a default setting, which can be changed once parameters within the loop are realized. In other embodiments, the window time unit interval may be variable throughout the operation of the electoral loop filter.

The electoral loop filter 320 uses time intervals and votes to make a decision whether to increment or decrement the phase of a local clock. The amount of phase adjustments under embodiments of the present invention is different than prior architectures, as the adjustments occur at established time periods according to the window time unit interval. Furthermore, adjustments occur according to a majority vote over a limited time window versus reaching a threshold vote over an unpredictable and possibly unlimited time period.

The bandwidth created by embodiments of the present invention is advantageous in conditions of low transition density where an increment or decrement will cause a move in the phase. In previous designs, no increment would be made until a threshold was met, thereby possibly causing a lack of tracking to occur and more phase error to accumulate.

Embodiments of the present invention make the decision-making process of the receiver tracking loop simpler, and because of this simplicity it becomes easier to reduce the loop latency of the receiver tracking loop. The accumulation of error because of wrong decisions in the receiver tracking loop may also be reduced. Furthermore, the phase error between the transmit clock and receive clock may be reduced by increasing the bandwidth of the tracking loop response and reducing potential overshoot by half. The improved bandwidth may allow embodiments of the present invention to track higher frequencies and amplitudes of jitter.

The phase increment or phase decrement signal produced by the electoral loop filter unit 320 is sent to the interpolator control unit 330 of receiver tracking unit 300. Interpolator control unit 330 provides the controls to produce a clock with variable phase. In one embodiment, it derives its output clock by using several phases of a local clock.

In some embodiments, interpolator current sources are controlled via a 64-bit long shift register. At any given time, 16 bits are set to ‘1’ and the rest of the bits are set to ‘0’. The location of the string of ‘1’s govern the phase of the interpolator output. A control mechanism in the interpolator unit will rotate these bits in a circular fashion based on the phase increment and phase decrement commands from the electoral loop filter. The output of interpolator unit 330 is a phase-adjusted local clock that may better track the embedded transmitted clock of the data stream from the transmitter. One skilled in the art will appreciate that embodiments of the interpolator control unit 330 could be implemented in a variety of ways, and are not necessarily limited to a 64-bit control register.

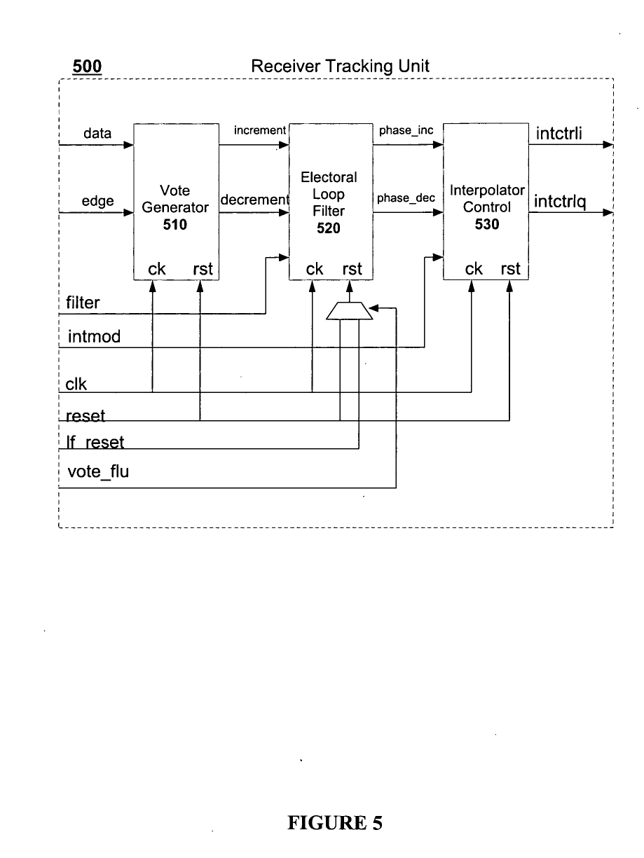

FIG. 5 illustrates a circuit diagram of one embodiment of a receiver tracking unit 500. In some embodiments, receiver tracking unit 500 may be the circuit level implementation of receiver tracking unit 300 of FIG. 3. Receiver tracking unit 500 includes phase comparator/vote generator unit 510, electoral loop filter 520, and interpolator control unit 530. In some embodiments, units 510, 520, and 530 correspond respectively to units 310, 320, and 330 of FIG. 3.

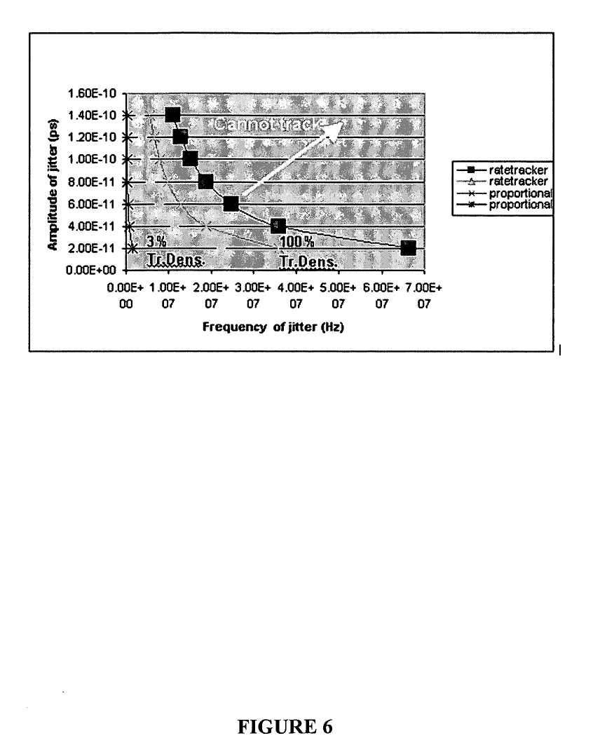

FIG. 6 is a graphical depiction of the bandwidth of the electoral loop filter when using window time unit intervals and votes at different transition densities. Also shown is the bandwidth of the proportional filter of previous architectures at lower transition densities. The Y-axis shows the amplitude of jitter, and the X-axis is the frequency of jitter that can be tracked. All amplitudes and frequencies below and to the left of a particular line can be tracked. As can be seen, using an electoral vote filter may allow more frequencies for an amount of jitter to be tracked as compared to a proportional filter.

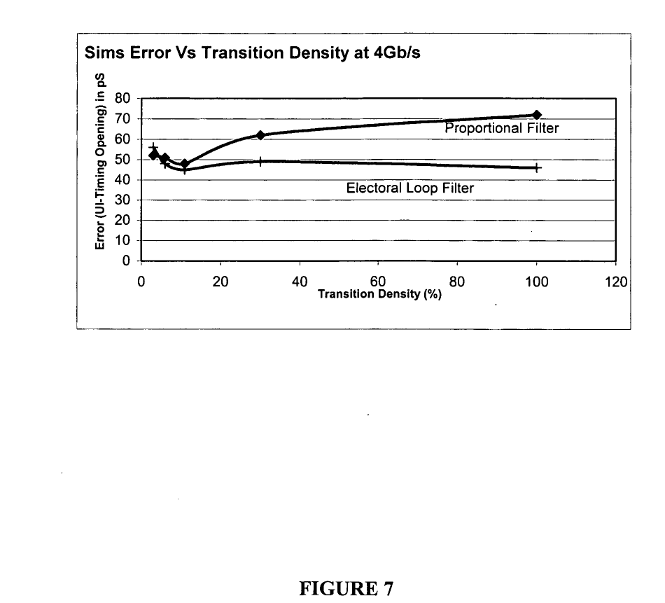

The idea behind tracking is to reduce phase error between the local and transmitted clocks in a data communication system. Embodiments of the present invention may have a higher tracking accuracy leading to improved link margins. FIG. 7 illustrates local Rx clock signal error as a function of transition density when employing embodiments of the electoral vote filter of the present invention versus the proportional filter of previous architectures. Embodiments of the electoral vote filter have a much flatter response over transition densities, as well as reducing phase error as compared to the previously implemented proportional filter. The flatter response may lead to less jitter induced by the use of votes during a window time unit interval in a system. In some transition density patterns, the embodiments of the electoral vote filter of the present invention may reduce the phase error by about as much as 40% as shown in FIG. 7.

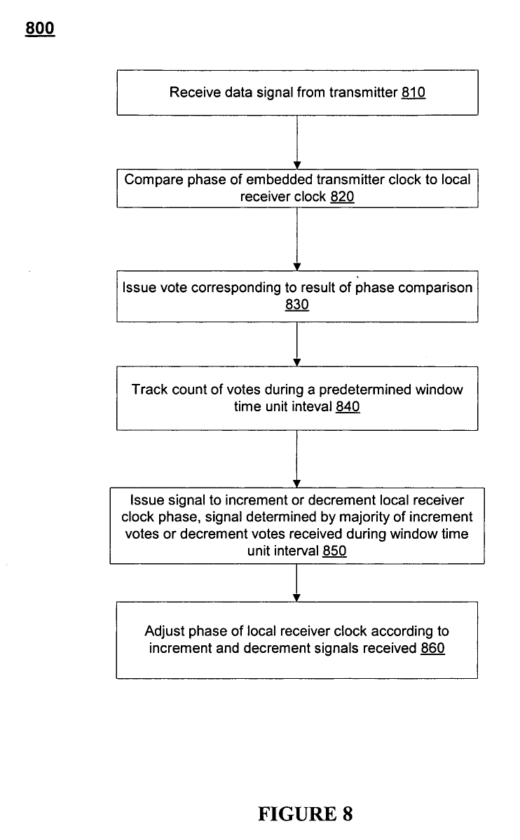

FIG. 8 is a flow diagram depicting a method 800 of improving bandwidth and reducing phase error in a receiver tracking unit. The following method is performed by a receiver tracking unit, such as receiver tracking unit 300 in FIG. 3. At processing block 810, a data signal is received from a transmitter. At processing block 820, the phase of the embedded transmitter clock data is compared to the phase of a local receiver clock. Then, at processing block 830, a vote is issued corresponding to the result of the phase comparison. At processing block 840, the count of the votes issued during a predetermined window time unit interval is tracked.

At processing block 850, a signal is issued to increment or decrement the local receiver clock phase. The signal is determined by the majority, either of increment votes or decrement votes, received during the window time unit interval. Finally, at processing block 860, the phase of the local receiver clock is adjusted according to the increment and decrement signals received.

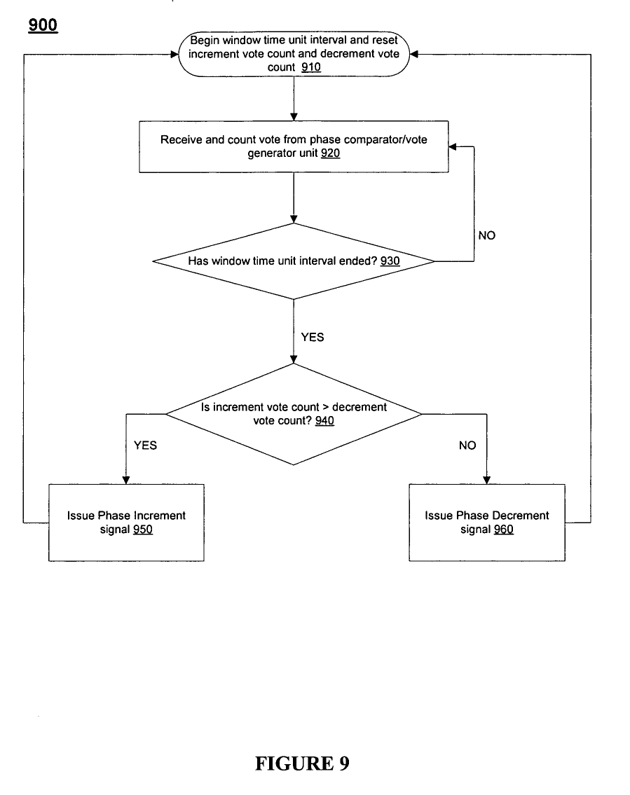

On a more detailed level, FIG. 9 is another flow diagram depicting a method 900 of improving bandwidth and reducing phase error through the use of an electoral loop filter. The following method is performed by an electoral loop filter. In one embodiment, method 900 is performed in electoral loop filter 320 of a receiver tracking unit.

At processing block 910, a window time unit interval begins and each of a increment vote count and a decrement vote count is reset. At processing block 920, a vote from the phase comparator/vote generator unit is received and counted. If the vote is an increment vote, the increment vote count is increased. If the vote is a decrement vote, the decrement vote count is increased. At decision block 930, it is determined whether the window time unit interval has ended. If not, then the loop continues at processing block 920 and another vote is received and counted. If the window time unit interval has ended, then the method continues at processing block 940.

At processing block 940 it is determined whether the increment vote count is greater than the decrement vote count. If the increment vote count is greater than the decrement vote count, then a phase increment signal is issued at processing block 950. If the decrement vote count is greater than the increment vote count, then a phase decrement signal is issued at processing block 960.

If the vote count is equal, some embodiments may assert a phase increment signal and other embodiment may assert a phase decrement signal. Further still, some embodiments may refer to the next vote in the electoral loop filter as a tie-breaker. Once a phase increment or phase decrement signal has been asserted, the process begins again at processing block 910 with a new window time unit interval.

Embodiments of the present invention may be used in products that implement high-speed input/output such as PCI (Peripheral Component Interconnect) Express, CSI (Computer System Interface), FBD (Fully Buffered DIMM), or Infiniband physical specifications. One skilled in the art will appreciate that embodiments of the present invention may be useful in other high-speed input/output communication products as well.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the invention.

What is claimed is:

1. An apparatus, comprising:
a phase comparator to generate indications based on phases of a local clock signal and transitions in a stream of received data;
an electoral loop filter to generate a phase shift signal based on the indications received from the phase comparator in a time interval; and
a local clock controller to adjust the local clock signal based on the phase shift signal generated from the electoral loop filter.

2. The apparatus of claim 1, wherein the indications generated by the phase comparator identify the position of the phase of the local clock signal as compared to the transitions in the received data.

3. The apparatus of claim 2, wherein the phase shift signal is issued whenever a majority of indications for a particular time interval indicate that the phase of the local clock signal should be incremented.

4. The apparatus of claim 2, wherein the phase shift signal is issued whenever the majority of indications for a particular time interval indicate that the phase of the local clock signal should be decremented.

5. The apparatus of claim 1, wherein the time interval is predetermined and fixed throughout the operation of the electoral loop filter.

6. The apparatus of claim 1, wherein the time interval is variable throughout the operation of the electoral loop filter.

7. The apparatus of claim 1, wherein the electoral loop filter further includes circuitry to determine the majority of indications asserted by the phase comparator.

8. An apparatus, comprising:
a front amplifier to receive data from an input/output link driven by a remote clock signal;
an interpolator to generate a local clock signal to track the remote clock signal embedded in the data; and
a tracking unit to compare phase information about the remote clock signal and the local clock signal and to dynamically adjust the phase of the local clock signal based on the comparison,
wherein the tracking unit is configured to dynamically adjust the phase by generating phase shift signals based on the phase comparisons during a time interval.

9. The apparatus of claim 8, wherein the interpolator generates the local clock signal based on the phase shift signals issued from the tracking unit.

10. The apparatus of claim 8, wherein the time interval is predetermined and fixed throughout the operation of the tracking unit.

11. A method, comprising:
tracking indications received from a phase comparator unit;
determining a majority of indications received during a window time unit interval; and
issuing a phase shift signal based on the majority of indications occurring during the window time unit interval.

12. The method of claim 11, wherein the indications from the phase comparator are generated by comparing a phase of an embedded remote clock within a received data signal with the phase of a local receiver clock.

13. The method of claim 11, further comprising adjusting the phase of a local receiver clock according to the phase shift signal.

14. The method of claim 11, wherein determining a majority of indications further includes determining the greater of a number of increment indications and a number of decrement indications received during the window time unit interval.

15. The method of claim 11, wherein the window time unit interval is predetermined and fixed.

16. The method of claim 11, where the window time unit interval is variable.

17. A system, comprising:
a transmitting device; and
a receiving device connected to the transmitting device by a data line, the receiving device further comprising
a phase comparator to generate indications based phases of a local clock signal and transitions in a stream of received data;
an electoral loop filter to generate a phase shift signal based on indications received from the phase comparator in a time interval; and
a local clock controller to adjust the local clock signal based on the phase shift signal generated from the electoral loop filter.

18. The system of claim 17, wherein the indications generated by the phase comparator identify the position of the phase of the local clock signal as compared to the transitions in the received data

19. The system of claim 18, wherein the indications generated by the phase comparator identify whether the phase of the local clock signal is leading or lagging as compared to the transitions in the received data.

20. The system of claim 18, wherein the phase shift signal is issued whenever the majority of indications for a particular time interval indicate that the phase of the local clock signal should be decremented.

21. The system of claim 17, wherein the time interval is predetermined and fixed throughout the operation of the electoral loop filter.

22. The system of claim 17, wherein the electoral loop filter further includes circuitry to determine the majority of indications asserted by the phase comparator.
